(19) United States
(12) Patent Application Publication
(10) Pub. No.: US 2022/0093486 A1
(43) Pub. Date: Mar. 24, 2022

(54) POWER SEMICONDUCTOR MODULE WITH CLAMPING DEVICE

(71) Applicant: Infineon Technologies AG, Neubiberg (DE)

(72) Inventors: Tomas Manuel Reiter, Munchen (DE); Elvis Keli, Bad Sassendorf (DE); Anthony Thomas, Muenchen (DE)

(21) Appl. No.: 17/027,772

(22) Filed: Sep. 22, 2020

(51) Int. Cl. H01L 23/40; H01L 23/498

(52) U.S. Cl. CPC H01L 23/4006; H01L 23/49811; H01L 2023/405; H01L 2023/4081; H01L 2023/4087

(57) ABSTRACT

A power semiconductor module includes: a carrier; a plurality of semiconductor dies attached to a first side of the carrier and electrically connected to form a circuit or part of a circuit; a cooling device at a second side of the carrier opposite the first side; a clamping device attached to the cooling device and pressing the carrier toward the cooling device such that the second side of the carrier is in thermal contact with the cooling device without having an intervening base plate between the carrier and the cooling device; and a first sensor device embedded in the clamping device or attached to an interior surface of the clamping device.

### BACKGROUND

Power semiconductor modules used in DC/AC inverter, DC/DC converter and AC/DC rectifier applications typically include a circuit carrier to which semiconductor dies (chips) such as transistor and/or diode dies are mounted. The circuit carrier may be a standard printed circuit board (PCB), a lead frame, a ceramic substrate or similar part. At least one side of the circuit carrier has a structured electric conductive area, where the semiconductor dies are attached by solder or other bonding process such as sintering. The opposite side of the semiconductor dies are connected with a second electrically conductive structure such as bond wires, metal clips, etc. The side of the circuit carrier where no dies are mounted is attached to a cooling system.

Power semiconductor modules are cooled by direct fluid cooling or with indirect cooling. Indirect cooled power modules are attached via thermal interface material to a cooling system. This thermal interface material fills cavities between the circuit carrier and the cooling system with thermally conductive material such as thermal grease. A high mechanical pressure from the circuit carrier to the cooling system is beneficial for the function of the thermal interface. Typically, greater pressure yields lower thermal resistance. Limits are given by the mechanical construction and robustness of the individual elements in the entire stack.

In some cases, a metal baseplate is used where the circuit carrier is mounted on the baseplate. The metal baseplate may have a convex form with respect to the cooling system. When the baseplate is fixed by screws to the cooling system, a defined mechanical pressure is ensured by this convex pre-shaping of the baseplate. However, metal baseplates are expensive. Also, complex and high-cost processes are used to attach a circuit carrier to a metal baseplate. For example, a wide solder area without voids is required and the baseplate must withstand high mechanical stress over the module lifetime. To overcome the high cost of baseplate-based power modules, so-called baseplate-less' power module constructions have been used. Baseplate-less power module constructions typically include a lid for ensuring partial pressure orthogonal to the circuit carrier.

### SUMMARY

According to an embodiment of a power semiconductor module, the power semiconductor module comprises: a carrier; a plurality of semiconductor dies attached to a first side of the carrier and electrically connected to form a circuit or part of a circuit; a cooling device at a second side of the carrier opposite the first side; a clamping device attached to the cooling device and pressing the carrier toward the cooling device such that the second side of the carrier is in thermal contact with the cooling device without having an intervening base plate between the carrier and the cooling device; and a first sensor device embedded in the clamping device or attached to an interior surface of the clamping device.

According to another embodiment of a power semiconductor module, the power semiconductor module comprises: a carrier; a plurality of semiconductor dies attached to a first side of the carrier and electrically connected to form a circuit or part of a circuit; a cooling device at a second side of the carrier opposite the first side; a clamping device attached to the cooling device and pressing the carrier toward the cooling device such that the second side of the carrier is in thermal contact with the cooling device without having an intervening base plate between the carrier and the cooling device, the clamping device comprising a cover member and a plurality of pressing members extending from the cover member in a direction toward the carrier, each one of the pressing members pressing against one of the semiconductor dies, a metal clip attached to one of the semiconductor dies, or the first side of the carrier; signal pins confined within the power semiconductor module between the carrier and the cover member of the clamping device, the signal pins configured to provide signal connections to the semiconductor dies; and a signal routing structure embedded in or attached to the cover member of the clamping device, wherein the signal pins connect to and terminate at the signal routing structure, wherein the signal routing structure is configured to route the signal connections to a connector that is accessible at a side of the cover member facing away from the carrier.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of an embodiment of a power semiconductor module.

FIG. 2 illustrates a cross-sectional view of another embodiment of a power semiconductor module.

FIG. 3 illustrates a cross-sectional view of another embodiment of a power semiconductor module.

FIG. 4 illustrates a cross-sectional view of another embodiment of a power semiconductor module.

FIG. 5 illustrates a cross-sectional view of another embodiment of a power semiconductor module.

FIG. 6 illustrates a cross-sectional view of another embodiment of a power semiconductor module.

FIG. 7 illustrates a cross-sectional view of another embodiment of a power semiconductor module.

FIG. 8 illustrates a cross-sectional view of another embodiment of a power semiconductor module.

### DETAILED DESCRIPTION

The embodiments described herein provide a baseplate-less power semiconductor module having a carrier such as a substrate, PCB, lead frame, etc. for accommodating one or more semiconductor dies, a clamping device which provides a clamping force orthogonal to the circuit carrier to ensure a good thermal connection from the carrier to a cooling system, and a sensor which is embedded in the clamping device or attached to an interior surface of the clamping device. In the case of a temperature sensor, a temperature sensor close to the semiconductor dies on the circuit carrier may provide useful information about operating conditions, and a control unit may protect the power module from overheating by reducing the power dissipation (e.g. limitation of switching frequency, control for lower currents, shutdown of the system, etc.). Other types of sensors may be embedded in the clamping device or attached to an interior surface of the clamping device, such as but not limited to a pressure sensor, a force sensor, and a current sensor, etc. More than one type of sensor may be embedded in the clamping device or attached to an interior surface of the clamping device.

Separately or in addition, the clamping device may be made with an isolating material such as a plastics material, at least in the sensor area to ensure a galvanic isolation of the sensor to the circuit on the carrier of the power module. Separately or in addition, the clamping device may implement metal clamps/springs to provide higher forces/pressure compared to plastics material. Separately or in addition, the clamping device may be realized by a combination of materials. Some clamping points/areas may be made with metal clamps/springs and others, especially where the sensors are positioned, may be made of plastics material. Separately or in addition, the material of the clamping device may be a high thermal conductivity material for additional heat transfer from the topside of the dies included in the power module to a thermal sink. Separately or in addition, each sensor embedded in the clamping device or attached to an interior surface of the clamping device may be implemented without galvanic isolation to the circuit carrier. This can be an advantage when a sensor needs a potential from the circuit carrier.

Separately or in addition, the clamping device may be realized to provide a clamping force directly on the semiconductor dies mounted to the circuit carrier, e.g., when metal clips are used instead of bond wires.

Separately or in addition, a sensor embedded in the clamping device or attached to an interior surface of the clamping device may be connected to sensor pins, which may be directly implemented in the clamping device. Separately or in addition, the sensor pins may be implemented as press-fit pins as the clamping device is intrinsically designed to handle forces orthogonal to the circuit carrier. During press-in, the clamping force is slightly higher than in normal operation over application lifetime. Separately or in addition, the clamping device may also implement one or more signal pins for the power module dies (e.g. gate, emitter, collector, etc.). The signal pins may also be press-fit pins. On the carrier substrate, rivets may be placed where press-fit pins are implemented in the clamping device are pressed in at the power module production site. The other side of the press-fit pins may be pressed in into a printed circuit board where gate drive and control logic may be implemented. The clamping device may implement all sensor and signal pins of the power module. Separately or in addition, the signal and sensor pins may be press-fit pins but instead may be springs, solder pins or other connection technology, or any combination thereof.

Separately or in addition, a sensor embedded in the clamping device or attached to an interior surface of the clamping device may be a thermal sensor to monitor the temperature of the circuit carrier, which correlates to the temperature of the cooling system and the die temperatures. For example, the thermal sensor may be an NTC (negative temperature coefficient) or PTC (positive temperature coefficient) resistor, diode, IR (infrared) or other temperature sensor.

Separately or in addition, a sensor embedded in the clamping device or attached to an interior surface of the clamping device may be a pressure/force sensor to monitor the clamping force of the clamping device.

Separately or in addition, a sensor embedded in the clamping device or attached to an interior surface of the clamping device may be a magnetic sensor to monitor currents on the circuit carrier.

Separately or in addition, a sensor embedded in the clamping device or attached to an interior surface of the clamping device may be a combined temperature, pressure, force, and/or current sensor.

Separately or in addition, a sensor embedded in the clamping device or attached to an interior surface of the clamping device may be implemented on a circuit carrier such as a printed circuit board.

Separately or in addition, the clamping device may be realized to have several pressure points/areas to the circuit carrier and more than one sensor position may be realized.

Separately or in addition, the clamping device may implement a signal layer where control and sensor signals are routed to, e.g., a connector to one or more sides of the power module. The clamping device may include a printed circuit board. Such a printed circuit board may be fully or partially molded into the clamping device.

Separately or in addition, and regardless of whether a sensor is embedded in the clamping device or attached to an interior surface of the clamping device, the clamping device may include a signal routing structure for routing signal connections to a connector that is accessible at a side of the clamping device facing away from the carrier.

The power semiconductor module embodiments described herein allow for a thermal sensor that may be pressed onto the carrier since the clamping device has the function to clamp the circuit carrier of the module to a cooling system. The thermal sensor may therefore always have a defined thermal coupling to certain parts on the circuit carrier. The sensor may be positioned very close to the semiconductor dies to provide a high thermal coupling. Pressure may be applied where needed, e.g., at the active dies and monitored. Each sensor does not require space on the expensive circuit carrier. Each sensor may be easily galvanically isolated since the sensors are not implemented on the circuit carrier. Each sensor may be a pressure/force sensor to monitor the clamping function of the clamping device, in case clamping force will degrade the thermal connection of the circuit carrier to the cooling system will degrade, and power derating may be required to avoid overheating. Different sensor positions may be accommodated, e.g., close to the semiconductor dies to monitor chip temperature, far away from the sensor to monitor more the coolant temperature, etc. The circuit carrier, e.g., for a B6 (3-phase) bridge rectifier may include three equal half bridge parts and the clamping device may be realized with three or more sensors. Yield loss from circuit carrier with dies and the clamping device with sensors may be decoupled as each part may be pre-tested individually. A modular power module also is possible. Equal carriers and dies may be combined with different clamping devices and sensors. Safety critical applications may make use of sensors, whereas low-cost applications may avoid the cost of sensors, but the same die/carrier production line may be used for both types of applications. Equal carriers and dies, e.g., in a half bridge configuration may be used and different variants of the clamping device may form a B6 or B12 bridge; a half bridge with n parallel half bridges; a B6 bridge with n parallel half bridges, etc. The clamping device may implement the signal routing.

Described next, with reference to the figures, are exemplary embodiments of power semiconductor modules.

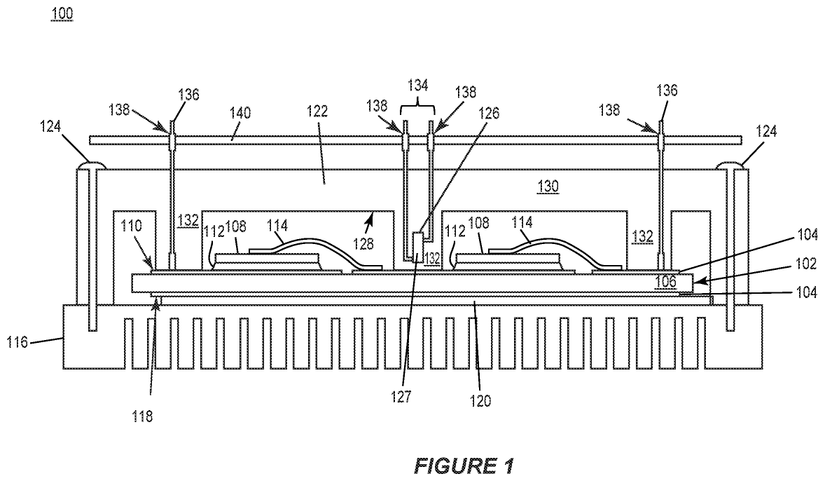

FIG. 1 illustrates a cross-sectional view of a power semiconductor module 100. The power semiconductor module 100 includes a carrier 102 such as a circuit board like a PCB (printed circuit board), a lead frame, a DBC (direct bonded copper) substrate, an AMB (active metal brazed) substrate, an IMS (insulated metal substrate), etc. For example, in the case of a DBC substrate, the carrier 102 may include a sheet of copper 104 bonded to one or both sides of a ceramic base 106. Each copper sheet 104 may be patterned or un-patterned. For example, the bottom copper sheet 104 may be un-patterned and the top copper sheet 104 may be patterned.

The power semiconductor module 100 also includes a plurality of semiconductor dies 108 attached to a first side 110 of the carrier 102 by a die attach material 112 such as solder, and electrically connected to form a circuit or part of a circuit. The carrier 102, e.g., the patterned top copper sheet 104 shown in FIG. 1, may form part of the electrical connections between the semiconductor dies 108. Additional connectors 114 such as metal clips, wire bonds, wire ribbons, etc. may be used to complete the electrical connections between the semiconductor dies 108 within the package 100. For example, the semiconductor dies 108 may include power transistors and/or power diodes and may be electrically connected in a half bridge or full bridge configuration. In this example, the power semiconductor module 100 is configured as a power rectifier module. However, this is just an example. The semiconductor dies 108 may be electrically connected within the power semiconductor module 100 to form any type of circuit or part of a circuit.

The power semiconductor module 100 further includes a cooling device 116 at a second side 118 of the carrier 102 opposite the first side 110. The cooling device 116 dissipates heat energy generated by the semiconductor dies 108 during operation. The cooling device 116 may provide passive or active cooling. In the case of active cooling, air or a liquid coolant is forced over a surface of the cooling device 116 facing away from the carrier 102.

The cooling device 116 may contact the carrier 102 or a thermal interface material 120 may be interposed between the carrier 102 and the cooling device 116. The thermal interface material 120 may include thermal grease, a gap pad, phase change material, etc. In the case of the carrier 102 being implemented as a DBC substrate, the bottom metallization 104 of the carrier 102 is in thermal contact with the cooling device 116. As explained above, a thermal interface material 120 may be interposed between the bottom metallization 104 of the carrier 102 and the cooling device 116 or the bottom metallization 104 of the carrier 102 may contact the cooling device 116.

The power semiconductor module 100 also includes a clamping device 122 attached to the cooling device 116 by fasteners 124 such as screws, bolts, etc. The clamping device 122 presses the carrier 102 toward the cooling device 116 such that the second side 118 of the carrier 102 is in thermal contact with the cooling device 116 without having an intervening base plate between the carrier 102 and the cooling device 116. As explained above, a thermal interface material 120 may however be interposed between the carrier 102 and the cooling device 116.

A first sensor device 126 is embedded in the clamping device 122 or attached to an interior surface 128 of the clamping device 122. The first sensor device 126 includes a sensor die 127 configured to perform one or more sensing functions such as but not limited to temperature sensing, pressure sensing, force sensing and current sensing.

In the case of sensing pressure/strain applied by the clamping device 122, the sensor die 127 may include a MEMS (microelectromechanical system) sensor, a piezoelectric sensor, etc. The thermal interface material 120 may cause the clamping device 122 to lose force. If the clamping device 122 is formed from a mold compound, plastic material may degrade at high temperature and therefore lose force. In each case, a pressure sensor could detect a change in pressure/force applied by the clamping device 122. The pressure sensor may be directly over a semiconductor die 108 or the carrier 102.

In the case of sensing temperature, the sensor die 127 may include an NTC (negative temperature coefficient) or PTC (positive temperature coefficient) sensor. The temperature sensor may be in close proximity to a semiconductor die.

In the case of sensing current, the sensor die 127 may include a magnetic sensor such as a Hall sensor. Hall sensors can measure AC or DC currents. A thermal sensor may also be included with a lookup table, to adjust the current (e.g. Hall) sensor based on temperature.

In the case of combined sensing, the sensor die 127 may sense both temperature and strain. Temperature sensing allows calibration of a strain sensor. Both sensors may be integrated in the same die 127, e.g., both sensors may be Si (silicon) sensors. The sensors, however, may instead be provided on different dies, e.g., a Si temp sensor and a piezoelectric strain sensor.

In one embodiment, the clamping device 122 comprises a mold compound and the first sensor device 126 is embedded in the mold compound. For example, the first sensor device 126 may be overmolded by mold compound. In another embodiment, the first sensor device 126 may be disposed in a cavity formed in the mold compound.

The clamping device 122 may be formed from a material other than mold compound, or combinations of materials. For example, the clamping device 122 may partly comprise an electrically insulative material such as a mold compound and partly comprise an electrically conductive material such as metal springs, etc.

More than one sensor device 126 may be embedded in the clamping device 122 or attached to the interior surface 128 of the clamping device 122 and the sensors 126 may be of the same or different type. For example, temperature and/or pressure and/or force and/or current sensor devices may be embedded in the clamping device 122 or attached to the interior surface 128 of the clamping device 122, or the first sensor device 126 may be capable of sensing more than one parameter (e.g. two or more of temperature, pressure, force and current). In the case of more that one sensor device, each additional sensor device may be embedded in or attached to a different part of the clamping device 122 than the first sensor device 126.

In one embodiment, the clamping device 122 comprises a cover member 130 and pressing members 132 extending from the cover member 130 in a direction toward the carrier 102. The pressing members 132 are vertical members of the clamping device 122 whereas the cover member 130 is a horizontal member that overlies and joins the vertical pressing members 132 in a common plane. Each pressing member 132 presses against a semiconductor die 108, a metal clip (not shown in FIG. 1) attached to a semiconductor die 108, or the first side 110 of the carrier 102. As shown in FIG. 1, the first sensor device 126 may be embedded in or attached to one of the pressing members 132.

The first sensor device 126 may receive an electric potential from the carrier 102. In other embodiments, the first sensor device 126 is galvanically isolated from the carrier 102, e.g., by the clamping device 122.

The first sensor device 126 may include terminals 134 that extend through the clamping device 122 in a direction facing away from the carrier 102. The sensor terminals 134 may be directly attached to the sensor die 127, or instead the sensor device 126 may be a through hole component for inserting in a plastic part. For example, the first sensor device 126 may be a through-hole component and the sensor terminals 134 provide connections for the through-hole component that protrude through the clamping device 122. The carrier 102 may include signal and power terminals 136 that likewise extend through the clamping device 122 in a direction facing away from the carrier 102. The terminals 134, 136 may be inserted into corresponding press-fit receptacles 138 of a circuit board 140 such as a PCB. The circuit board 140 may include circuitry (not shown in FIG. 1) for controlling the semiconductor dies 108 included in the power semiconductor module 100.

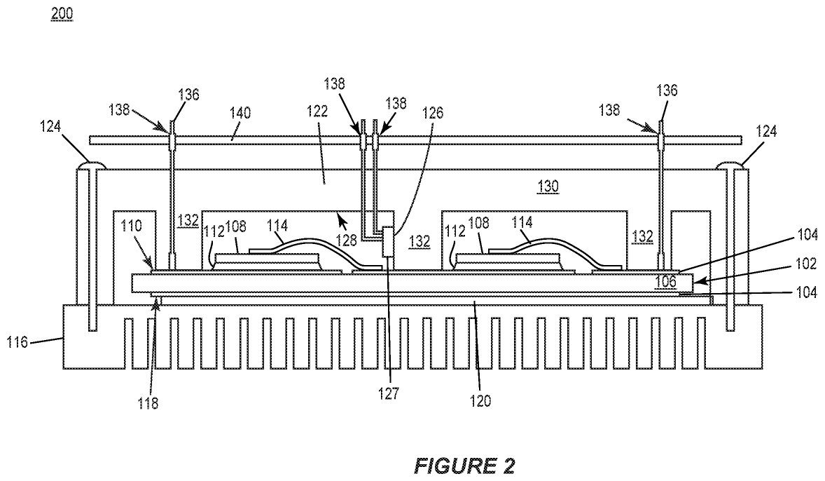

FIG. 2 illustrates a cross-sectional view of a power semiconductor module 200. The embodiment shown in FIG. 2 is similar to the embodiment shown in FIG. 1. Different, however, the first sensor device 126 is attached to the interior surface 128 of the clamping device 122 instead of being embedded in the clamping device 122. The first sensor device 126 may be attached to the interior surface 128 of the clamping device 122 by an adhesive tape, glue, etc.

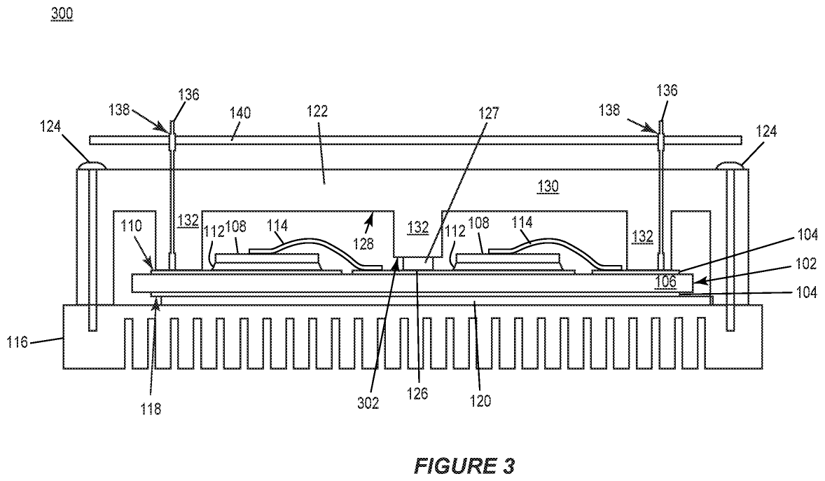

FIG. 3 illustrates a cross-sectional view of a power semiconductor module 300. The embodiment shown in FIG. 3 is similar to the embodiments shown in FIGS. 1 and 2. Different, however, the first sensor device 126 is attached to a surface 302 of one of the pressing members 132 of the clamping device 122 that faces the carrier 102. The first sensor device 126 may be held in place by the pressure exerted by the clamping device 122. The first sensor device 126 may be attached to the bottom surface 302 of the corresponding pressing member 132 and/or to the first side 110 of the carrier 102. The electrical connections to the first sensor device 126 are out of view in FIG. 3. As explained above, the first sensor device 126 may be electrically connected to the carrier 102 or electrically insulated from the carrier 102.

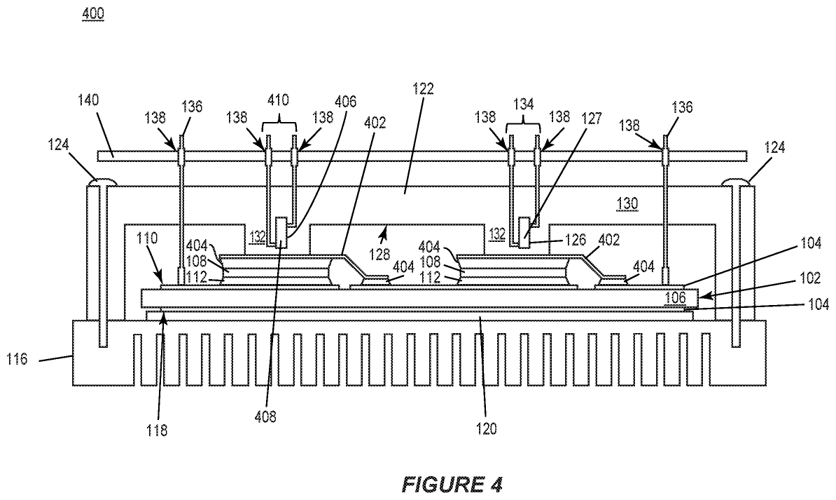

FIG. 4 illustrates a cross-sectional view of a power semiconductor module 400. The embodiment shown in FIG. 4 is similar to the embodiments shown in FIGS. 1 through 3. Different, however, metal clips 402 are used to provide electrical connections between one or more terminals at the top side of the semiconductor dies 108 and the carrier 102. The metal clips 402 may be attached to the top side of the semiconductor dies 108 and to the carrier 102 via a die attach material 404 such as solder. The pressing members 132 of the clamping device 122 press against a corresponding one of the metal clips attached to a respective semiconductor die 108, according to the embodiment illustrated in FIG. 4. As previously explained herein, the power semiconductor module 400 may also include at least one additional sensor device 406 embedded in or attached to a different part of the clamping device 122 than the first sensor device 126. Each additional sensor device 406 includes a sensor die 408 configured to perform one or more sensing functions such as but not limited to temperature sensing, pressure sensing, force sensing and current sensing. Each additional sensor device 406 may include terminals 410 that extend through the clamping device 122 in a direction facing away from the carrier 102 and which are inserted into corresponding press-fit receptacles 138 of a circuit board 140.

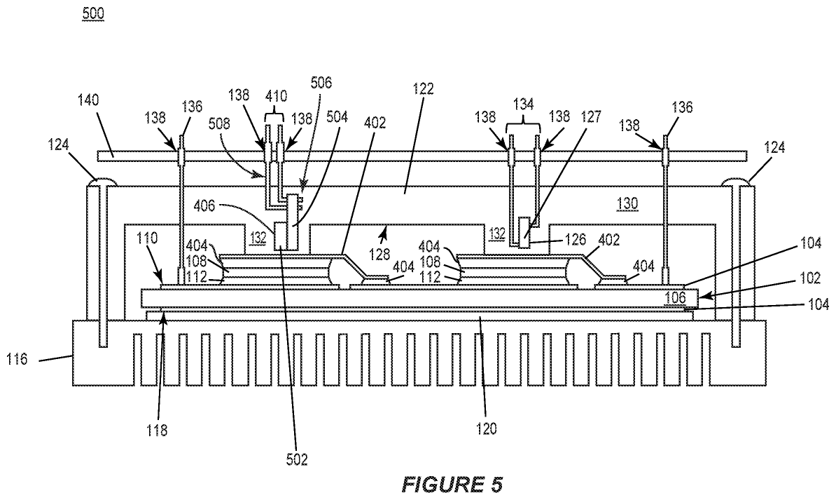

FIG. 5 illustrates a cross-sectional view of a power semiconductor module 500. The embodiment shown in FIG. 5 is similar to the embodiment shown in FIG. 4. Different, however, at least one sensor device 406 includes a sensor die 502 configured to perform one or more sensing functions such as but not limited to temperature sensing, pressure sensing, force sensing and current sensing. The sensor die 502 is attached to a circuit board 504 of the sensor device 406, such as a PCB. The terminals 408 of the sensor device 502 are attached to the circuit board 504 at a first end 506 and protrude through the clamping device 122 at a second end 508 opposite the first end 506.

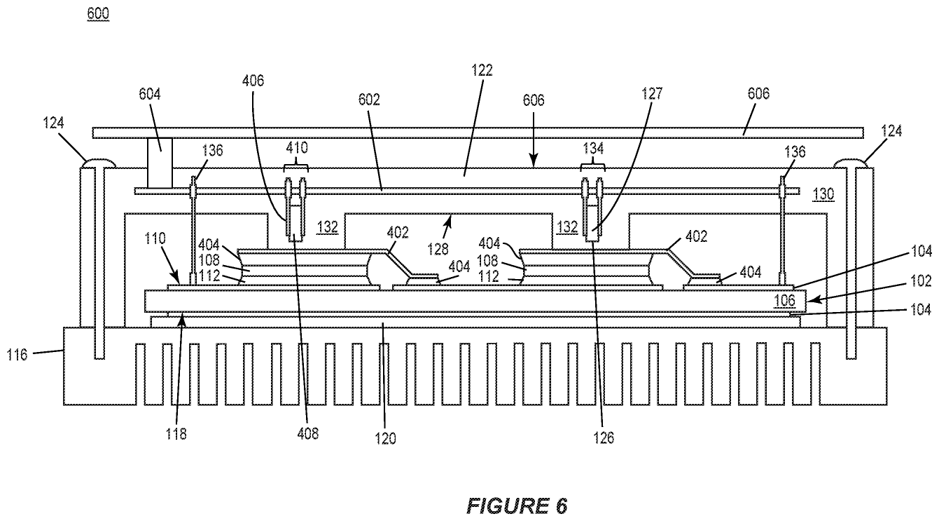

FIG. 6 illustrates a cross-sectional view of a power semiconductor module 600. The embodiment shown in FIG. 6 is similar to the embodiment shown in FIG. 4. Different, however, at least the signal pins 136 extending from the carrier 102 are confined within the power semiconductor module 600 between the carrier 102 and the cover member 130 of the clamping device 122, the signal pins 136 being configured to provide signal connections to the semiconductor dies 108 and/or the sensor device(s) 126, 406.

The power semiconductor module 600 further includes a signal routing structure 602 embedded in or attached to the cover member 130 of the clamping device 122. The signal routing structure 602 provides signal routing within the power semiconductor module 600. The signal pins 136 extending from the carrier 102 connect to and terminate at the signal routing structure 602. In one embodiment, the signal routing structure 602 is a circuit board such as a PCB. In another embodiment, the signal routing structure 602 is formed by metal areas such as Cu areas overmolded in a plastic material such as mold compound.

The signal pins 136 extending from the carrier 102 may be press-fit into the signal routing structure 602 at the opposite end from the carrier 102. Other types of connections between the signal pins 136 and the signal routing structure 602 may be used such as but not limited to springs, solder balls/bumps, pins, Cu pillars, etc. The signal routing structure 602 may also route power connections such as supply voltage(s), ground, etc. for the semiconductor dies 108 included in the power semiconductor module 600.

According to the embodiment illustrated in FIG. 6, the signal pins 136 extending from the carrier 102 do not protrude outside the clamping device 122. Instead, the signal routing structure 602 routes the signal (and possibly power) connections to a connector 604 that is externally accessible at a side 606 of the cover member 130 of the clamping device 122 facing away from the carrier 102. The connector 604 is configured to interface with another system 606 such as a circuit board, another power semiconductor module, etc. The connector 604 aggregates signals into and out of the power semiconductor module 600 via the signal routing structure 602.

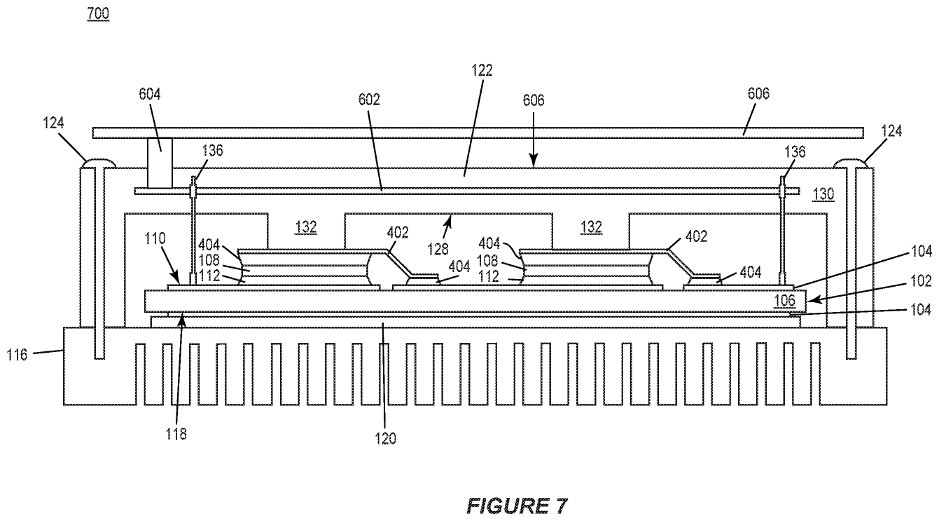

FIG. 7 illustrates a cross-sectional view of a power semiconductor module 700. The embodiment shown in FIG. 7 is similar to the embodiment shown in FIG. 6. Different, however, no sensor devices are included in the power semiconductor module 700. According to this embodiment, the power semiconductor module 700 includes the carrier 102, semiconductor dies 108 attached to the first side 110 of the carrier 102 and electrically connected to form a circuit or part of a circuit, the cooling device 116 at the second side 118 of the carrier 102, the clamping device 122 attached to the cooling device 116 and pressing the carrier 102 toward the cooling device 116, signal and optionally power pins 136 confined within the power semiconductor module 700 between the carrier 102 and the cover member 130 of the clamping device 122, and the signal routing structure 602 embedded in or attached to the cover member 130 of the clamping device 122. The signal (and possibly power) pins 136 connect to and terminate at the signal routing structure 602, and the signal routing structure 602 routes the signal (and possibly power) connections to the connector 604 that is accessible at the side 606 of the cover member 130 of the clamping device 122 facing away from the carrier 102, as previously explained herein. The carrier 102 is in thermal contact with the cooling device 116 without having an intervening base plate between the carrier 102 and the cooling device 116, also as previously explained herein, and each pressing member 132 of the clamping device 122 presses against a respective semiconductor die 108, a corresponding metal clip 402, or the first side 110 of the carrier 102.

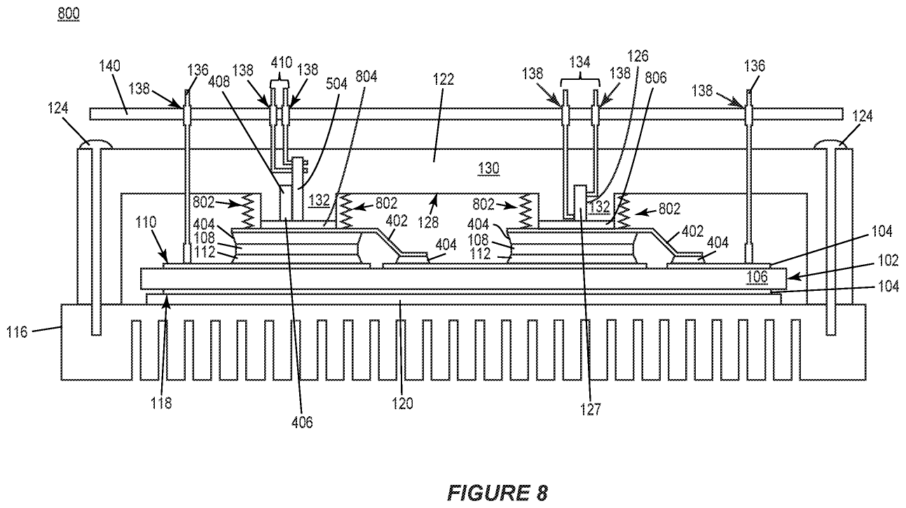

FIG. 8 illustrates a cross-sectional view of a power semiconductor module 800. The embodiment shown in FIG. 8 is similar to the embodiment shown in FIG. 5. Different, however, the clamping device 122 further includes one or more compression springs 802 adjacent the pressing members 132 of the clamping device 122. The compression springs 802 ensure a stable force/pressure to the carrier 102 over the application lifetime. One or more of the sensor devices 126, 406 may be galvanically isolated in the clamping device 122. A high elastic thermal interface material 804 may be provided for ensuring a good thermal connection to a temperature sensor 408 in the clamping device 122. If a sensor device 126 is exposed at the bottom side of a pressing member 132 of the clamping device, as shown in the righthand side of FIG. 8, thermal interface material 806 with good electrical isolation characteristics may be provided for ensuring good galvanic isolation from the carrier 102. However, as previously explained herein and depending on the type of sensor device, one or more of the sensor devices 126, 408 may be in electrical contact with the carrier 102.

Although the present disclosure is not so limited, the following numbered examples demonstrate one or more aspects of the disclosure.

Example 1. A power semiconductor module, the power semiconductor module comprises: a carrier; a plurality of semiconductor dies attached to a first side of the carrier and electrically connected to form a circuit or part of a circuit; a cooling device at a second side of the carrier opposite the first side; a clamping device attached to the cooling device and pressing the carrier toward the cooling device such that the second side of the carrier is in thermal contact with the cooling device without having an intervening base plate between the carrier and the cooling device; and a first sensor device embedded in the clamping device or attached to an interior surface of the clamping device.

Example 2. The power semiconductor module of example 1, wherein the carrier is a direct bonded copper (DBC) substrate comprising a ceramic base, a first metallization at a first side of the ceramic base and a second metallization at a second side of the ceramic base opposite the first side of the ceramic base, wherein the semiconductor dies are attached to the first metallization of the DBC substrate, and wherein the second metallization of the DBC substrate is in thermal contact with the cooling device.

Example 3. The power semiconductor module of example 1 or 2, wherein the clamping device comprises a mold compound, and wherein the first sensor device is embedded in the mold compound.

Example 4. The power semiconductor module of example 3, wherein the first sensor device is overmolded by the mold compound.

Example 5. The power semiconductor module of example 3, wherein the first sensor device is disposed in a cavity formed in the mold compound.

Example 6. The power semiconductor module of any of examples 1 through 5, wherein the clamping device comprises a cover member and a plurality of pressing members extending from the cover member in a direction toward the carrier, wherein each one of the pressing members presses against one of the semiconductor dies, a metal clip attached to one of the semiconductor dies, or the first side of the carrier, and wherein the first sensor device is embedded in or attached to one of the pressing members.

Example 7. The power semiconductor module of example 6, wherein the first sensor device is attached to a surface of one of the pressing members that faces the carrier.

Example 8. The power semiconductor module of example 6 or 7, wherein the clamping device further comprises one or more compression springs adjacent the pressing members.

Example 9. The power semiconductor module of any of examples 6 through 8, further comprising: signal pins confined within the power semiconductor module between the carrier and the cover member of the clamping device, the signal pins configured to provide signal connections to the semiconductor dies and/or the first sensor device; and a signal routing structure embedded in or attached to the cover member of the clamping device, wherein the signal pins connect to and terminate at the signal routing structure, wherein the signal routing structure is configured to route the signal connections to a connector that is accessible at a side of the cover member facing away from the carrier.

Example 10. The power semiconductor module of example 9, wherein the signal routing structure is a circuit board.

Example 11. The power semiconductor module of example 9 or 10, wherein the signal pins are press-fit into the signal routing structure.

Example 12. The power semiconductor module of any of examples 1 through 11, wherein the first sensor device comprises terminals that extend through the clamping device in a direction facing away from the carrier.

Example 13. The power semiconductor module of example 12, wherein the first sensor device comprises a sensor die attached to a circuit board, and wherein the terminals are attached to the circuit board at a first end and protrude through the clamping device at a second end opposite the first end.

Example 14. The power semiconductor module of example 12, wherein the first sensor device is a through-hole component, and wherein the terminals provide connections for the through-hole component that protrude through the clamping device.

Example 15. The power semiconductor module of any of examples 1 through 14, wherein the first sensor device is configured to sense at least one of temperature, pressure, force and current.

Example 16. The power semiconductor module of any of examples 1 through 15, further comprising a second sensor device embedded in or attached to a different part of the clamping device than the first sensor device.

Example 17. The power semiconductor module of any of examples 1 through 16, wherein the first sensor device receives an electric potential from the carrier.

Example 18. A power semiconductor module, comprising: a carrier; a plurality of semiconductor dies attached to a first side of the carrier and electrically connected to form a circuit or part of a circuit; a cooling device at a second side of the carrier opposite the first side; a clamping device attached to the cooling device and pressing the carrier toward the cooling device such that the second side of the carrier is in thermal contact with the cooling device without having an intervening base plate between the carrier and the cooling device, the clamping device comprising a cover member and a plurality of pressing members extending from the cover member in a direction toward the carrier, each one of the pressing members pressing against one of the semiconductor dies, a metal clip attached to one of the semiconductor dies, or the first side of the carrier; signal pins confined within the power semiconductor module between the carrier and the cover member of the clamping device, the signal pins configured to provide signal connections to the semiconductor dies; and a signal routing structure embedded in or attached to the cover member of the clamping device, wherein the signal pins connect to and terminate at the signal routing structure, wherein the signal routing structure is configured to route the signal connections to a connector that is accessible at a side of the cover member facing away from the carrier.

Example 19. The power semiconductor module of example 18, wherein the signal routing structure is a circuit board.

Example 20. The power semiconductor module of example 18 or 19, wherein the signal pins are press-fit into the signal routing structure.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor module, comprising:
a carrier;
a plurality of semiconductor dies attached to a first side of the carrier and electrically connected to form a circuit or part of a circuit;
a cooling device at a second side of the carrier opposite the first side;
a clamping device attached to the cooling device and pressing the carrier toward the cooling device such that the second side of the carrier is in thermal contact with the cooling device without having an intervening base plate between the carrier and the cooling device; and
a first sensor device embedded in the clamping device or attached to an interior surface of the clamping device.

2. The power semiconductor module of claim 1, wherein the carrier is a direct bonded copper (DBC) substrate comprising a ceramic base, a first metallization at a first side of the ceramic base and a second metallization at a second side of the ceramic base opposite the first side of the ceramic base, wherein the semiconductor dies are attached to the first metallization of the DBC substrate, and wherein the second metallization of the DBC substrate is in thermal contact with the cooling device.

3. The power semiconductor module of claim 1, wherein the clamping device comprises a mold compound, and wherein the first sensor device is embedded in the mold compound.

4. The power semiconductor module of claim 3, wherein the first sensor device is overmolded by the mold compound.

5. The power semiconductor module of claim 3, wherein the first sensor device is disposed in a cavity formed in the mold compound.

6. The power semiconductor module of claim 1, wherein the clamping device comprises a cover member and a plurality of pressing members extending from the cover member in a direction toward the carrier, wherein each one of the pressing members presses against one of the semiconductor dies, a metal clip attached to one of the semiconductor dies, or the first side of the carrier, and wherein the first sensor device is embedded in or attached to one of the pressing members.

7. The power semiconductor module of claim 6, wherein the first sensor device is attached to a surface of one of the pressing members that faces the carrier.

8. The power semiconductor module of claim 6, wherein the clamping device further comprises one or more compression springs adjacent the pressing members.

9. The power semiconductor module of claim 6, further comprising:
signal pins confined within the power semiconductor module between the carrier and the cover member of the clamping device, the signal pins configured to provide signal connections to the semiconductor dies and/or the first sensor device; and
a signal routing structure embedded in or attached to the cover member of the clamping device,
wherein the signal pins connect to and terminate at the signal routing structure,
wherein the signal routing structure is configured to route the signal connections to a connector that is accessible at a side of the cover member facing away from the carrier.

10. The power semiconductor module of claim 9, wherein the signal routing structure is a circuit board.

11. The power semiconductor module of claim 9, wherein the signal pins are press-fit into the signal routing structure.

12. The power semiconductor module of claim 1, wherein the first sensor device comprises terminals that extend through the clamping device in a direction facing away from the carrier.

13. The power semiconductor module of claim 12, wherein the first sensor device comprises a sensor die attached to a circuit board, and wherein the terminals are attached to the circuit board at a first end and protrude through the clamping device at a second end opposite the first end.

14. The power semiconductor module of claim 12, wherein the first sensor device is a through-hole component, and wherein the terminals provide connections for the through-hole component that protrude through the clamping device.

15. The power semiconductor module of claim 1, wherein the first sensor device is configured to sense at least one of temperature, pressure, force and current.

16. The power semiconductor module of claim 1, further comprising a second sensor device embedded in or attached to a different part of the clamping device than the first sensor device.

17. The power semiconductor module of claim 1, wherein the first sensor device receives an electric potential from the carrier.

18. A power semiconductor module, comprising:
a carrier;
a plurality of semiconductor dies attached to a first side of the carrier and electrically connected to form a circuit or part of a circuit;
a cooling device at a second side of the carrier opposite the first side;
a clamping device attached to the cooling device and pressing the carrier toward the cooling device such that the second side of the carrier is in thermal contact with the cooling device without having an intervening base plate between the carrier and the cooling device, the clamping device comprising a cover member and a plurality of pressing members extending from the cover member in a direction toward the carrier, each one of the pressing members pressing against one of the semiconductor dies, a metal clip attached to one of the semiconductor dies, or the first side of the carrier;
signal pins confined within the power semiconductor module between the carrier and the cover member of the clamping device, the signal pins configured to provide signal connections to the semiconductor dies; and
a signal routing structure embedded in or attached to the cover member of the clamping device,
wherein the signal pins connect to and terminate at the signal routing structure,
wherein the signal routing structure is configured to route the signal connections to a connector that is accessible at a side of the cover member facing away from the carrier.

19. The power semiconductor module of claim 18, wherein the signal routing structure is a circuit board.

20. The power semiconductor module of claim 18, wherein the signal pins are press-fit into the signal routing structure.
